(19) United States
(12) Patent Application Publication
(10) Pub. No.: US 2015/0301085 A1
(43) Pub. Date: Oct. 22, 2015

(54) Automatically Capturing Data Sets of Interest from a Data Acquisition Data Stream

(71) Applicant: NATIONAL INSTRUMENTS CORPORATION, Austin, TX (US)

(72) Inventors: Kyle R. Bryson, Austin, TX (US); Christopher S. Ficklin, Cedar Park, TX (US); Jeffrey J. Kellam, Austin, TX (US); Andrew L. Chao, Austin, TX (US)

(73) Assignee: NATIONAL INSTRUMENTS CORPORATION, Austin, TX (US)

(21) Appl. No.: 14/258,368

(22) Filed: Apr. 22, 2014

(51) Int. Cl. G01R 13/00

(52) U.S. Cl. CPC G01R 13/00

(57) ABSTRACT

Capturing datasets of interest from a data acquisition data stream. An acquired dataset may be received from a measurement device. The acquired dataset may include measurement data from measurements of one or more physical phenomena acquired by the measurement device, and may be a current dataset in a sequence of datasets acquired by the measurement device. The acquired dataset is buffered, resulting in a buffered dataset. One or more thresholds specifying datasets of interest may be automatically determined based on the buffered dataset or one or more previously acquired datasets. The buffered dataset may be automatically analyzed with respect to the one or more thresholds, and a determination may be made as to whether the buffered dataset is a dataset of interest based on said automatically analyzing. In response to determining that the buffered dataset is a dataset of interest, the buffered dataset may be stored in a storage medium.

### FIELD OF THE INVENTION

The present invention relates to the field of measurement, and more particularly to systems and methods for capturing data sets of interest from a data acquisition data stream.

### DESCRIPTION OF THE RELATED ART

In industrial and scientific data acquisition (DAQ) processes, it is often desirable to identify datasets, e.g., waveforms, of interest, e.g., regarding a device under test (DUT). For example, engineers or scientists using oscilloscopes and/or logic analyzers are often looking at displays that constantly update data, and want to select and save certain datasets for further analysis or storage. This is often accomplished by hitting a ‘single’ or ‘stop’ button immediately before or after the time of the event of interest.

This presents two challenges not well addressed by existing solutions:

1. Holding test probes onto sources of the signals of interest on the DUT can be difficult and often requires two hands or awkward angles that make pressing a button without disrupting the measurement difficult.

2. Events that occur rarely in the midst of more frequent events may appear briefly on an instrument, but have been overwritten before the user can stop the instrument to inspect them. Existing solutions require the user to anticipate the nature of such an event and to set up a trigger condition that will only occur on the rare event and not the frequent events. Depending on the signal and triggering capabilities of the instrument, this may be impossible, the user may not be able to successfully identify the unique triggering condition that will capture the rare event, or the user may find the task too difficult to attempt.

Accordingly, improved systems and methods for capturing datasets (e.g., waveforms) of interest are desired.

### SUMMARY OF THE INVENTION

Various embodiments of a system and method for capturing data sets of interest from a data acquisition data stream are presented below.

An acquired dataset may be received from a measurement device, where the acquired dataset includes measurement data from measurements of one or more physical phenomena acquired by the measurement device. For example, the dataset may be a current dataset in a sequence (i.e., stream) of datasets acquired by the measurement device. The measurement data may be any type of measurement data desired. For example, in some embodiments, each acquired dataset may include waveform data, although any other form of measurement data may be used as desired. Additionally, the particular phenomena represented by the measurement data may be of any type. Thus, for example, the waveform data may be or include voltage data.

The acquired dataset may be buffered, resulting in a buffered dataset. In other words, the received acquired dataset may be stored in a buffer, i.e., a memory buffer, from which the dataset may be subsequently read. In some embodiments, the buffered dataset may be displayed.

One or more thresholds may be automatically determined based on the buffered dataset or one or more previously acquired datasets, where the one or more thresholds specify datasets of interest. Said another way, datasets of interest (e.g., of interest to the user, a process, etc.) may be specified via one or more thresholds (i.e., threshold values) to be applied to the data sets to identify those of interest. These thresholds may be static, e.g., retrieved from a file, or may be dynamic, e.g., determined in response to user input and/or based on the current acquired dataset or one or more previous acquired datasets, as will be described in detail below.

The buffered dataset may be automatically analyzed with respect to the one or more thresholds. For example, the method may compare data in or of the buffered dataset to the one or more thresholds. Note that any types of analysis may be employed as desired. For example, the may simply compare the acquired data itself to the one or more thresholds, or may process the data in some way and compare the results to the one or more thresholds, e.g., computing moving averages and comparing them to a threshold value, calculating standard deviation of the dataset and comparing to a respective threshold, etc.

A determination may be made as to whether the buffered dataset is a dataset of interest based on the automatic analysis, and the buffered dataset may be stored in a storage medium (i.e., a memory medium) in response to determining that the buffered dataset is a dataset of interest. In various embodiments, the storage medium may itself be a buffer, e.g., in a volatile memory such as RAM, or may be a persistent (non-volatile) storage medium, e.g., flash memory, disk drive, etc. In one embodiment, user feedback may be provided in response to said determining that the buffered dataset is a dataset of interest. For example, an audible, visual, or haptic cue may be provided to the user to indicate determination of the dataset of interest.

In some embodiments, the method may further include repeating the above receiving, buffering, automatically determining one or more thresholds, analyzing, and determining whether the buffered dataset is a dataset of interest for each acquired dataset in the sequence of datasets, one or more times in an iterative manner. Moreover, for each buffered dataset that meets the desired criteria, the repeating may further include saving the buffered dataset (of interest).

In one embodiment, a dataset that is determined to be of interest may be saved to a short buffer that is available to the user (or process) for further analysis or persistent storage. In one embodiment, the method may include displaying each acquired dataset via a display device in response to receiving the acquired dataset. For example, a graphical user interface (GUI) may be provided in which a current dataset (in this case, waveform data) is displayed in the top window or display of the GUI (displayed on a display device). The GUI may further illustrate a buffer (or storage medium) for captured datasets of interest, e.g., as a “filmstrip”, along with display of the acquired dataset, e.g., below the display of the current dataset. It should be noted that the visual “filmstrip” metaphor is but one way to illustrate this buffer, and that any other illustrations or metaphors may be used as desired, and displayed in any manner desired, e.g., above the display of the acquired dataset, to the side, etc.

In some embodiments, the captured dataset of interest may be displayed at a lower resolution than that of the displayed corresponding buffered dataset. For example, in one embodiment, the method may take a “screenshot” of the displayed buffered dataset, and reduce the screenshot to a thumbnail image, e.g., displayed in the “filmstrip” (or other GUI element or structure). Note that saving the dataset of interest may include saving all of the buffered dataset. Additionally, or alternatively, the dataset of interest may be processed prior to saving, e.g., filtered, smoothed, indexed, etc., as desired.

In one embodiment, the user may interact with the thumbnail image, e.g., to view the image/data in greater detail (higher resolution), to view additional data associated with but not contained in the thumbnail image, to manipulate the image (e.g., with modifications, annotations, additional cursors, additional measurements, and so forth), to save the image or additional data to some designated storage, e.g., a file, to designate or use the data contained in the thumbnail as a reference waveform, e.g., which may be overlaid on new datasets, or to flag it for further viewing, e.g., in an application. For example, the method may include receiving user input selecting a first dataset of interest of the sequence of datasets of interest. In response to this user input, the method may perform one or more of: displaying the first dataset of interest, displaying additional data associated with but not contained in the first dataset of interest, augmenting the first dataset of interest in response to further user input, including adding one or more of: annotations to the first dataset of interest, one or more cursors to the first dataset of interest, or additional measurement values to the first dataset of interest, saving the first dataset of interest to another storage medium, e.g., long term storage, flagging the first dataset for more detailed viewing or analysis, loading the first dataset of interest in an analysis tool for further analysis, or specifying the first dataset of interest as a reference dataset for analyzing subsequent acquired datasets, among others.

Due to the repeating of the above method elements, the method may further include displaying a sequence of datasets of interest resulting from the repeating of the saving step. Following the above, the sequence of datasets of interest may be displayed at a lower resolution than the acquired datasets, e.g., as a sequence of thumbnail images of the datasets of interest. Thus, displaying the sequence of datasets of interest may include displaying a sequence of thumbnail images of the datasets of interest. Note that the sequence of datasets may include datasets of data received on one or more channels, and the data of such datasets may differ in form, e.g., sinusoidal waveforms, triangular waveform, etc.

In one embodiment, images/datasets of interest not saved or flagged (for saving) by the time the filmstrip (or other GUI element/structure) is filled, i.e., upon reaching some maximum number of currently displayed datasets of interest (e.g., thumbnail images), may be automatically deleted, e.g., may “slide off” the filmstrip as newer images are added to the other side of the filmstrip. In other words, the “filmstrip” (or other GUI element) or buffer, may operate as a queue, where in case of an overflow the oldest images/datasets of interest are dropped from the display, and possibly deleted from the storage medium in which they are stored.

Note than in various embodiments, there may be numerous factors that determine or characterize datasets of interest, and thus the analyzing may identify any of a wide variety of attributes of the acquired dataset(s). For example, the analyzing may include one or more of the following (among others:
a) identifying presence or absence of a specified signal in the acquired dataset; an unconnected analog probe will often show characteristics such as a mean value near zero and low standard deviation and/or RMS (root mean square). Note that absence of signal on enabled signals (or channels) generally indicates that the data are not of interest.
b) identifying presence of a new signal in the acquired dataset, or identifying a difference of (or change in) a signal in the acquired dataset with respect to one or more previous acquired datasets or a specified reference dataset, where the difference exceeds a specified threshold; when a user moves a probe to a new signal, or a signal changes characteristics substantially, this may indicate new data of interest. Such a change in signal may be identified based on any of a variety of measurement characteristics of the signal, including, but not limited to, mean value, frequency, amplitude, RMS, and standard deviation.
c) identifying stable presence of a new signal in the acquired dataset; while connecting/holding probes to a DUT, a user may sequentially connect them to the correct probe locations, and may encounter transient events while connecting or may briefly connect them to incorrect probe locations. A series of datasets with consistent, similar measurement characteristics (e.g., mean value, frequency, etc.), but unique or distinct from previously identified signals, may indicate that the user has settled on a new probe location of interest, and that the dataset is of interest.
d) identifying an outlier or anomalous dataset with respect to previous and subsequent datasets, e.g., anomalies in repetitive events; many common measurements and trigger configurations yield a trigger configuration that occurs thousands or millions of times per second, and most or all of these datasets generally contain very similar data to the datasets immediately before and after them. When an anomaly or unusual condition occurs, a single dataset will have different characteristics (e.g., mean, frequency, etc.), but the following (next) dataset will resume the prior consistently similar behavior. An anomalous or unusual dataset such as this may be of interest.

Accordingly, the analyzing may include comparing one or more of the following against respective thresholds of the one or more thresholds: mean value of the buffered dataset, standard deviation of the buffered dataset, frequency of a signal in the dataset, or amplitude of a signal in the dataset, among others. Similarly, determining whether the dataset is a dataset of interest may include determining one or more of: presence of a signal in the dataset, difference of the signal in the dataset from a signal in an immediately previous dataset, stability of the signal in the dataset with respect to the signal in one or more immediately previous datasets, or stability of signal presence of the signal in the dataset with respect to the signal in one or more immediately previous datasets, among others.

Thus, various embodiments of the techniques disclosed herein may provide for intelligent capture of datasets of interest in a stream or sequence of acquired datasets.

### BRIEF DESCRIPTION OF THE DRAWINGS

A better understanding of the present invention can be obtained when the following detailed description of the preferred embodiment is considered in conjunction with the following drawings, in which:

FIG. 1A illustrates an exemplary computer (e.g., instrument) configured to implement an embodiment of the present invention;

FIG. 1B illustrates a network system comprising the exemplary computer of FIG. 1A coupled to a computer system, where the network system is configured to implement an embodiment of the present invention;

FIG. 2A illustrates an instrumentation control system, according to one embodiment;

FIG. 2B illustrates an industrial automation system, according to one embodiment;

FIG. 3A is a high level block diagram of an exemplary system which may implement embodiments of the present invention;

FIG. 3B illustrates an exemplary system which may perform control and/or simulation functions utilizing embodiments of the present invention;

FIG. 4 is an exemplary block diagram of the computer systems of FIGS. 1B, 2A, 2B, and 3B;

FIG. 5 is a flowchart diagram illustrating one embodiment of a method for automatically capturing data sets of interest from a data acquisition data stream;

FIG. 6A illustrates display of a measurement data of an acquired dataset from a sequence of acquired datasets, according to one embodiment;

FIG. 6B illustrates a visual indication to a user that the data set of FIG. 6A has been captured, according to one embodiment;

FIG. 6C illustrates a stored thumbnail image of the captured dataset of FIG. 6B, according to one embodiment;

FIG. 6D illustrates display of a measurement results data image that includes the dataset of FIG. 6A as well as a dataset from a new signal, according to one embodiment;

FIG. 6E illustrates a visual indication to a user that a second dataset has been captured, according to one embodiment; and

FIG. 6F illustrates addition of a stored thumbnail image of the captured second dataset of FIG. 6E, according to one embodiment.

While the invention is susceptible to various modifications and alternative forms, specific embodiments thereof are shown by way of example in the drawings and are herein described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE INVENTION

### Incorporation by Reference

The following references are hereby incorporated by reference in their entirety as though fully and completely set forth herein:

U.S. Pat. No. 4,914,568 titled “Graphical System for Modeling a Process and Associated Method,” issued on Apr. 3, 1990.

U.S. Pat. No. 5,481,741 titled “Method and Apparatus for Providing Attribute Nodes in a Graphical Data Flow Environment”.

U.S. Pat. No. 6,173,438 titled “Embedded Graphical Programming System” filed Aug. 18, 1997.

U.S. Pat. No. 6,219,628 titled “System and Method for Configuring an Instrument to Perform Measurement Functions Utilizing Conversion of Graphical Programs into Hardware Implementations,” filed Aug. 18, 1997.

U.S. Pat. No. 7,210,117 titled “System and Method for Programmatically Generating a Graphical Program in Response to Program Information,” filed Dec. 20, 2000.

### TERMS

The following is a glossary of terms used in the present application:

Memory Medium—Any of various types of memory devices or storage devices. The term “memory medium” is intended to include an installation medium, e.g., a CD-ROM, floppy disks 104, or tape device; a computer system memory or random access memory such as DRAM, DDR RAM, SRAM, EDO RAM, Rambus RAM, etc.; a non-volatile memory such as a Flash, magnetic media, e.g., a hard drive, or optical storage; registers, or other similar types of memory elements, etc. The memory medium may comprise other types of memory as well or combinations thereof. In addition, the memory medium may be located in a first computer in which the programs are executed, or may be located in a second different computer which connects to the first computer over a network, such as the Internet. In the latter instance, the second computer may provide program instructions to the first computer for execution. The term “memory medium” may include two or more memory mediums which may reside in different locations, e.g., in different computers that are connected over a network.

Carrier Medium—a memory medium as described above, as well as a physical transmission medium, such as a bus, network, and/or other physical transmission medium that conveys signals such as electrical, electromagnetic, or digital signals.

Programmable Hardware Element—includes various hardware devices comprising multiple programmable function blocks connected via a programmable interconnect. Examples include FPGAs (Field Programmable Gate Arrays), PLDs (Programmable Logic Devices), FPOAs (Field Programmable Object Arrays), and CPLDs (Complex PLDs). The programmable function blocks may range from fine grained (combinatorial logic or look up tables) to coarse grained (arithmetic logic units or processor cores). A programmable hardware element may also be referred to as “reconfigurable logic”.

Software Program—the term “software program” is intended to have the full breadth of its ordinary meaning, and includes any type of program instructions, code, script and/or data, or combinations thereof, that may be stored in a memory medium and executed by a processor. Exemplary software programs include programs written in text-based programming languages, such as C, C++, PASCAL, FORTRAN, COBOL, JAVA, assembly language, etc.; graphical programs (programs written in graphical programming languages); assembly language programs; programs that have been compiled to machine language; scripts; and other types of executable software. A software program may comprise two or more software programs that interoperate in some manner. Note that various embodiments described herein may be implemented by a computer or software program. A software program may be stored as program instructions on a memory medium.

Hardware Configuration Program—a program, e.g., a netlist or bit file, that can be used to program or configure a programmable hardware element.

Program—the term “program” is intended to have the full breadth of its ordinary meaning. The term “program” includes 1) a software program which may be stored in a memory and is executable by a processor or 2) a hardware configuration program useable for configuring a programmable hardware element.

Graphical Program—A program comprising a plurality of interconnected nodes or icons, wherein the plurality of interconnected nodes or icons visually indicate functionality of the program. The interconnected nodes or icons are graphical source code for the program. Graphical function nodes may also be referred to as blocks.

The following provides examples of various aspects of graphical programs. The following examples and discussion are not intended to limit the above definition of graphical program, but rather provide examples of what the term “graphical program” encompasses:

The nodes in a graphical program may be connected in one or more of a data flow, control flow, and/or execution flow format. The nodes may also be connected in a “signal flow” format, which is a subset of data flow.

Exemplary graphical program development environments which may be used to create graphical programs include LabVIEW®, DasyLab™, DiaDem™ and Matrixx/SystemBuild™ from National Instruments, Simulink® from the MathWorks, VEE™ from Agilent, WiT™ from Coreco, Vision Program Manager™ from PPT Vision, SoftWIRE™ from Measurement Computing, Sanscript™ from Northwoods Software, Khoros™ from Khoral Research, SnapMaster™ from HEM Data, VisSim™ from Visual Solutions, ObjectBench™ by SES (Scientific and Engineering Software), and VisiDAQ™ from Advantech, among others.

The term “graphical program” includes models or block diagrams created in graphical modeling environments, wherein the model or block diagram comprises interconnected blocks (i.e., nodes) or icons that visually indicate operation of the model or block diagram; exemplary graphical modeling environments include Simulink®, SystemBuild™, VisSim™, Hypersignal Block Diagram™, etc.

A graphical program may be represented in the memory of the computer system as data structures and/or program instructions. The graphical program, e.g., these data structures and/or program instructions, may be compiled or interpreted to produce machine language that accomplishes the desired method or process as shown in the graphical program.

Input data to a graphical program may be received from any of various sources, such as from a device, unit under test, a process being measured or controlled, another computer program, a database, or from a file. Also, a user may input data to a graphical program or virtual instrument using a graphical user interface, e.g., a front panel.

A graphical program may optionally have a GUI associated with the graphical program. In this case, the plurality of interconnected blocks or nodes are often referred to as the block diagram portion of the graphical program.

Node—In the context of a graphical program, an element that may be included in a graphical program. The graphical program nodes (or simply nodes) in a graphical program may also be referred to as blocks. A node may have an associated icon that represents the node in the graphical program, as well as underlying code and/or data that implements functionality of the node. Exemplary nodes (or blocks) include function nodes, sub-program nodes, terminal nodes, structure nodes, etc. Nodes may be connected together in a graphical program by connection icons or wires.

Data Flow Program—A Software Program in which the program architecture is that of a directed graph specifying the flow of data through the program, and thus functions execute whenever the necessary input data are available. Data flow programs can be contrasted with procedural programs, which specify an execution flow of computations to be performed. As used herein “data flow” or “data flow programs” refer to “dynamically-scheduled data flow” and/or “statically-defined data flow”.

Graphical Data Flow Program (or Graphical Data Flow Diagram)—A Graphical Program which is also a Data Flow Program. A Graphical Data Flow Program comprises a plurality of interconnected nodes (blocks), wherein at least a subset of the connections among the nodes visually indicate that data produced by one node is used by another node. A LabVIEW VI is one example of a graphical data flow program. A Simulink block diagram is another example of a graphical data flow program.

Graphical User Interface—this term is intended to have the full breadth of its ordinary meaning. The term “Graphical User Interface” is often abbreviated to “GUI”. A GUI may comprise only one or more input GUI elements, only one or more output GUI elements, or both input and output GUI elements.

The following provides examples of various aspects of GUIs. The following examples and discussion are not intended to limit the ordinary meaning of GUI, but rather provide examples of what the term “graphical user interface” encompasses:

A GUI may comprise a single window having one or more GUI Elements, or may comprise a plurality of individual GUI Elements (or individual windows each having one or more GUI Elements), wherein the individual GUI Elements or windows may optionally be tiled together.

A GUI may be associated with a graphical program. In this instance, various mechanisms may be used to connect GUI Elements in the GUI with nodes in the graphical program. For example, when Input Controls and Output Indicators are created in the GUI, corresponding nodes (e.g., terminals) may be automatically created in the graphical program or block diagram. Alternatively, the user can place terminal nodes in the block diagram which may cause the display of corresponding GUI Elements front panel objects in the GUI, either at edit time or later at run time. As another example, the GUI may comprise GUI Elements embedded in the block diagram portion of the graphical program.

Front Panel—A Graphical User Interface that includes input controls and output indicators, and which enables a user to interactively control or manipulate the input being provided to a program, and view output of the program, while the program is executing.

A front panel is a type of GUI. A front panel may be associated with a graphical program as described above.

In an instrumentation application, the front panel can be analogized to the front panel of an instrument. In an industrial automation application the front panel can be analogized to the MMI (Man Machine Interface) of a device. The user may adjust the controls on the front panel to affect the input and view the output on the respective indicators.

Graphical User Interface Element—an element of a graphical user interface, such as for providing input or displaying output. Exemplary graphical user interface elements comprise input controls and output indicators.

Input Control—a graphical user interface element for providing user input to a program. An input control displays the value input by the user and is capable of being manipulated at the discretion of the user. Exemplary input controls comprise dials, knobs, sliders, input text boxes, etc.

Output Indicator—a graphical user interface element for displaying output from a program. Exemplary output indicators include charts, graphs, gauges, output text boxes, numeric displays, etc. An output indicator is sometimes referred to as an “output control”.

Computer System—any of various types of computing or processing systems, including a personal computer system (PC), mainframe computer system, workstation, network appliance, Internet appliance, personal digital assistant (PDA), television system, grid computing system, measurement device, instrument, or other device or combinations of devices. In general, the term “computer system” can be broadly defined to encompass any device (or combination of devices) having at least one processor that executes instructions from a memory medium.

Measurement Device—includes instruments, data acquisition devices, smart sensors, and any of various types of devices that are configured to acquire and/or store data. A measurement device may also optionally be further configured to analyze or process the acquired or stored data. Examples of a measurement device include an instrument, such as a traditional stand-alone “box” instrument, a computer-based instrument (instrument on a card) or external instrument, a data acquisition card, a device external to a computer that operates similarly to a data acquisition card, a smart sensor, one or more DAQ or measurement cards or modules in a chassis, an image acquisition device, such as an image acquisition (or machine vision) card (also called a video capture board) or smart camera, a motion control device, a robot having machine vision, and other similar types of devices. Exemplary “stand-alone” instruments include oscilloscopes, multimeters, signal analyzers, arbitrary waveform generators, spectroscopes, and similar measurement, test, or automation instruments.

A measurement device may be further configured to perform control functions, e.g., in response to analysis of the acquired or stored data. For example, the measurement device may send a control signal to an external system, such as a motion control system or to a sensor, in response to particular data. A measurement device may also be configured to perform automation functions, i.e., may receive and analyze data, and issue automation control signals in response.

Measurement Results Data—refers to data resulting from one or more measurements. Thus, “measurement results data capture image”, or “measurement results capture image”, or simply “measurement results image”, refers to an image that captures measurement results (data), such as a screenshot of measurement waveform data, e.g., that may be generated by or for a GUI of a computer controlled or implemented measurement device/instrument. Other variants may also apply, e.g., “measurement data image”, “measurement capture image”, and so forth.

The term “measurement data” may at times be used to specifically refer to measurement results data, or, to refer to any kind of data associated with measurement, which may include requirements or configuration data, etc. Generally, the context of use will indicate which of these meanings is intended.

Automatically—refers to an action or operation performed by a computer system (e.g., software executed by the computer system) or device (e.g., circuitry, programmable hardware elements, ASICs, etc.), without user input directly specifying or performing the action or operation. Thus the term “automatically” is in contrast to an operation being manually performed or specified by the user, where the user provides input to directly perform the operation. An automatic procedure may be initiated by input provided by the user, but the subsequent actions that are performed “automatically” are not specified by the user, i.e., are not performed “manually”, where the user specifies each action to perform. For example, a user filling out an electronic form by selecting each field and providing input specifying information (e.g., by typing information, selecting check boxes, radio selections, etc.) is filling out the form manually, even though the computer system must update the form in response to the user actions. The form may be automatically filled out by the computer system where the computer system (e.g., software executing on the computer system) analyzes the fields of the form and fills in the form without any user input specifying the answers to the fields. As indicated above, the user may invoke the automatic filling of the form, but is not involved in the actual filling of the form (e.g., the user is not manually specifying answers to fields but rather they are being automatically completed). The present specification provides various examples of operations being automatically performed in response to actions the user has taken.

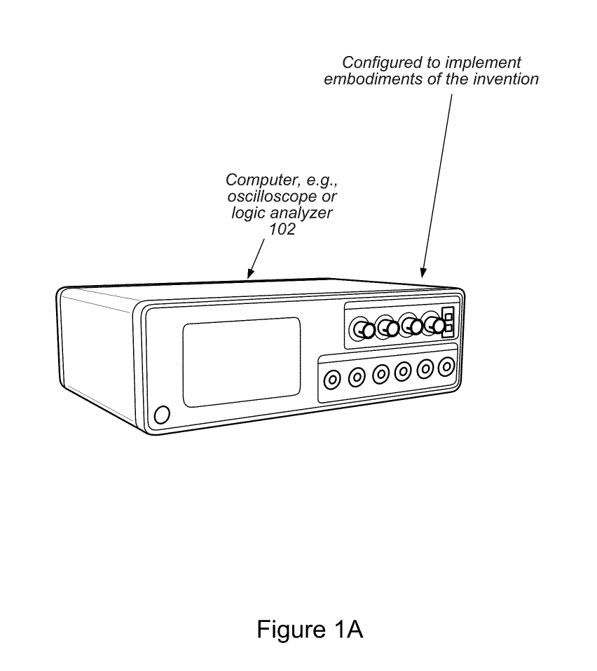

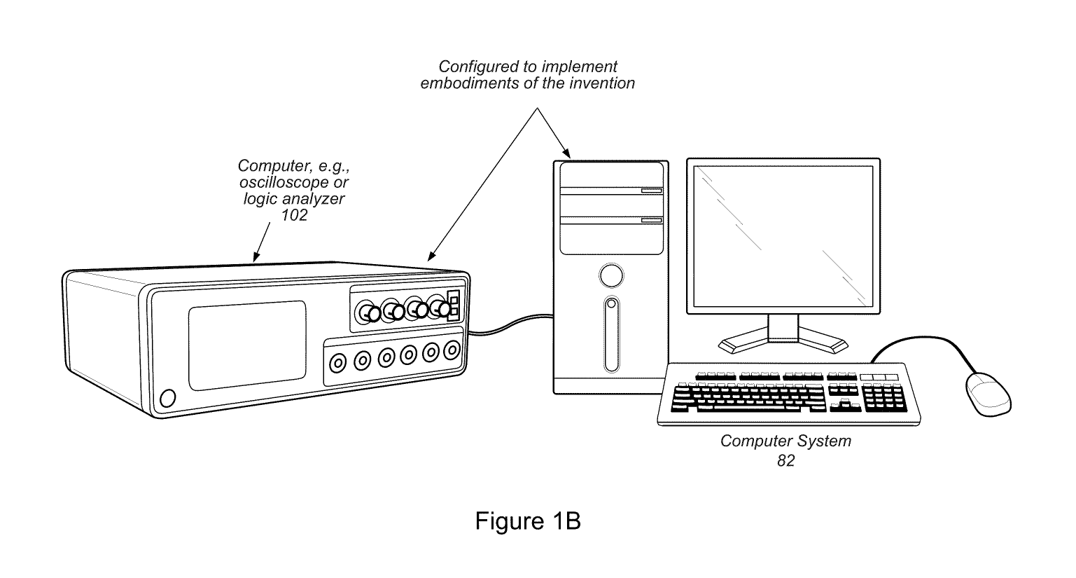

### FIG. 1A—Computer System

FIG. 1A illustrates a computer 102, such as an oscilloscope or logic analyzer, configured to implement embodiments of the present invention. Embodiments of methods for capturing data sets of interest from a data acquisition data stream are described below.

Note that the computer 102 shown is exemplary only, and that any of a wide variety of computing devices may be used as desired, e.g., electronic instruments, desktop computers or workstations, and so forth. As shown, the computer 102 may include display capabilities and controls whereby a user may manipulate or configure operation of the computer.

The computer system 102 may include at least one memory medium on which one or more computer programs or software components according to one embodiment of the present invention may be stored. For example, the memory medium may store one or more programs, e.g., graphical programs, which are executable to perform the methods described herein. Additionally, the memory medium may store a programming development environment application, e.g., a graphical programming development environment application, such as the LabVIEW™ graphical program development environment provided by National Instruments Corporation, used to create and/or execute such programs. The memory medium may also store operating system software, as well as other software for operation of the computer system. Various embodiments further include receiving or storing instructions and/or data implemented in accordance with the foregoing description upon a carrier medium.

### FIG. 1B—Computer Network

FIG. 1B illustrates a system including a first computer system 102 that is coupled to a second computer system 82. The first computer system 102 may be coupled via a network 84 (or a computer bus) to the second computer system 82. The computer systems 102 and 82 may each be any of various types, as desired. The network 84 can also be any of various types, including a LAN (local area network), WAN (wide area network), the Internet, or an Intranet, among others. The computer systems 102 and 82 may execute a virtual instrument (VI), e.g., a graphical program, in a distributed fashion. For example, computer 102 may execute a first portion of the block diagram of a graphical program and computer system 82 may execute a second portion of the block diagram of the graphical program. As another example, computer 102 may display the graphical user interface of a graphical program and computer system 82 may execute the block diagram of the graphical program. In a further exemplary embodiment, the computer 82 may be used as a user interface to interact with the computer (or instrument) 102, which may perform most or all of the functionality disclosed herein.

In one embodiment, the graphical user interface of the graphical program may be displayed on a display device of the computer system 102, and the block diagram may execute on a device coupled to the computer system 102. The device may include a programmable hardware element and/or may include a processor and memory medium which may execute a real time operating system. In one embodiment, the graphical program may be downloaded and executed on the device. For example, an application development environment with which the graphical program is associated may provide support for downloading a graphical program for execution on the device in a real time system. Of course, the above distributed functionality may also be applied to text-based programs.

Thus, in various embodiments, the techniques disclosed herein may be performed by software executing on the first computer 102, e.g., the instrument, on a second computer 82, e.g., a PC, tablet, etc., communicatively coupled to the first computer 102, or a combination of both.

### Exemplary Systems

Embodiments of the present invention may be involved with performing test and/or measurement functions; controlling and/or modeling instrumentation or industrial automation hardware; modeling and simulation functions, e.g., modeling or simulating a device or product being developed or tested, etc. Exemplary test applications where the program may be used include hardware-in-the-loop testing and rapid control prototyping, among others.

However, it is noted that embodiments of the present invention can be used for a plethora of applications and is not limited to the above applications. In other words, applications discussed in the present description are exemplary only, and embodiments of the present invention may be used in any of various types of systems. Thus, embodiments of the system and method of the present invention is configured to be used in any of various types of applications, including the control of other types of devices such as multimedia devices, video devices, audio devices, telephony devices, Internet devices, etc., as well as general purpose software applications such as word processing, spreadsheets, network control, network monitoring, financial applications, games, etc.

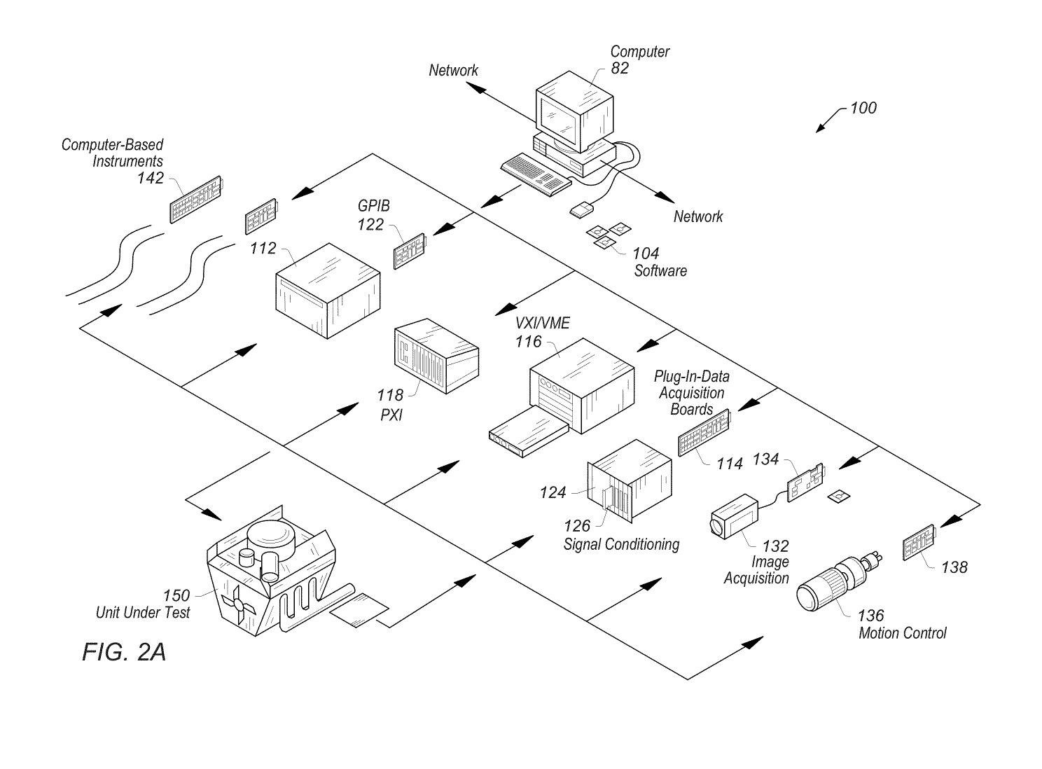

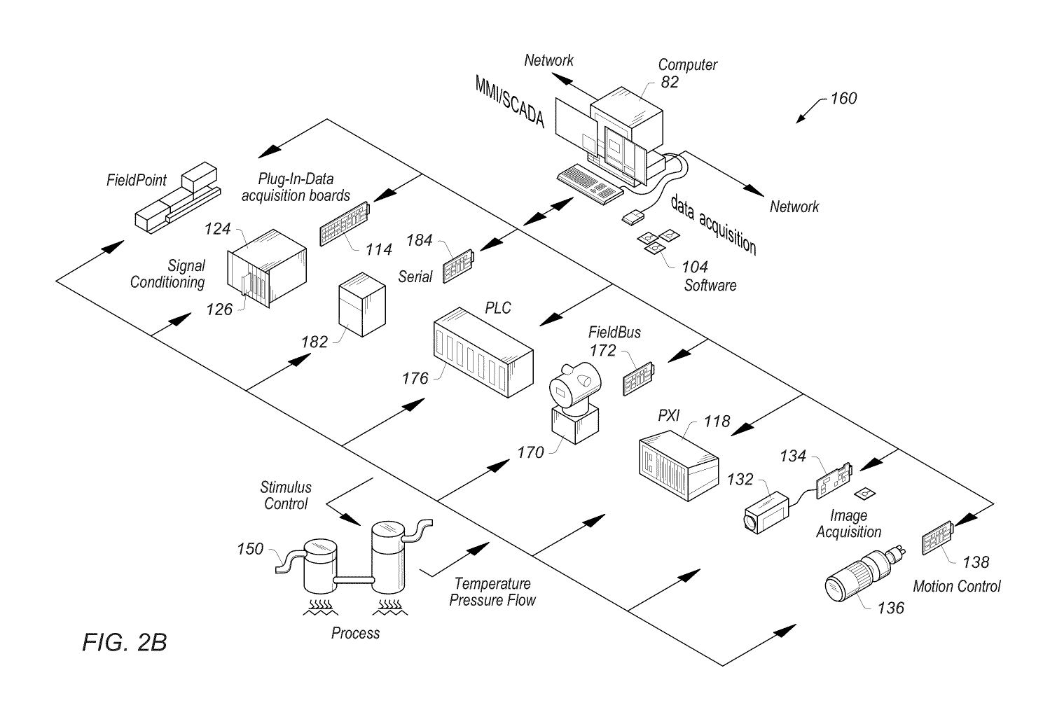

FIG. 2A illustrates an exemplary instrumentation control system 100 which may implement embodiments of the invention. The system 100 comprises a host computer 82 which couples to one or more instruments. The host computer 82 may comprise a CPU, a display screen, memory, and one or more input devices such as a mouse or keyboard as shown. The computer 82 may operate with the one or more instruments to analyze, measure or control a unit under test (UUT) or process 150.

The one or more instruments may include a GPIB instrument 112 and associated GPIB interface card 122, a data acquisition board 114 inserted into or otherwise coupled with chassis 124 with associated signal conditioning circuitry 126, a VXI instrument 116, a PXI instrument 118, a video device or camera 132 and associated image acquisition (or machine vision) card 134, a motion control device 136 and associated motion control interface card 138, and/or one or more computer based instrument cards 142, among other types of devices. The computer system may couple to and operate with one or more of these instruments. The instruments may be coupled to the unit under test (UUT) or process 150, or may be coupled to receive field signals, typically generated by transducers. The system 100 may be used in a data acquisition and control application, in a test and measurement application, an image processing or machine vision application, a process control application, a man-machine interface application, a simulation application, or a hardware-in-the-loop validation application, among others.

FIG. 2B illustrates an exemplary industrial automation system 160 which may implement embodiments of the invention. The industrial automation system 160 is similar to the instrumentation or test and measurement system 100 shown in FIG. 2A. Elements which are similar or identical to elements in FIG. 2A have the same reference numerals for convenience. The system 160 may comprise a computer 82 which couples to one or more devices or instruments. The computer 82 may comprise a CPU, a display screen, memory, and one or more input devices such as a mouse or keyboard as shown. The computer 82 may operate with the one or more devices to perform an automation function with respect to a process or device 150, such as MMI (Man Machine Interface), SCADA (Supervisory Control and Data Acquisition), portable or distributed data acquisition, process control, advanced analysis, or other control, among others.

The one or more devices may include a data acquisition board 114 inserted into or otherwise coupled with chassis 124 with associated signal conditioning circuitry 126, a PXI instrument 118, a video device 132 and associated image acquisition card 134, a motion control device 136 and associated motion control interface card 138, a fieldbus device 170 and associated fieldbus interface card 172, a PLC (Programmable Logic Controller) 176, a serial instrument 182 and associated serial interface card 184, or a distributed data acquisition system, such as the Fieldpoint system available from National Instruments, among other types of devices.

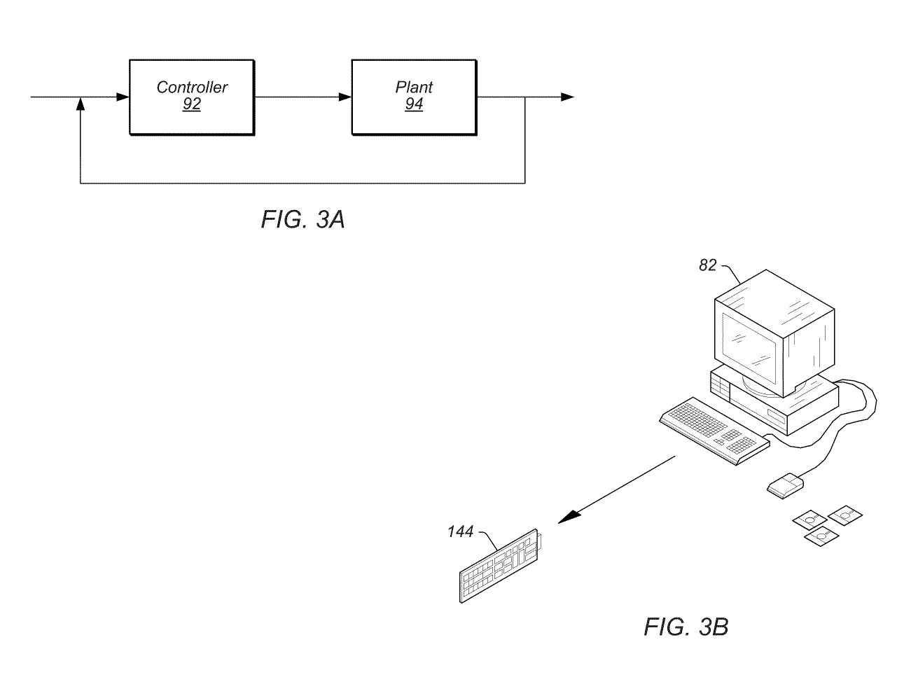

FIG. 3A is a high level block diagram of an exemplary system which may execute or utilize graphical programs (or text-based programs). FIG. 3A illustrates a general high-level block diagram of a generic control and/or simulation system which comprises a controller 92 and a plant 94. The controller 92 represents a control system/algorithm the user may be trying to develop. The plant 94 represents the system the user may be trying to control. For example, if the user is designing an ECU for a car, the controller 92 is the ECU and the plant 94 is the car's engine (and possibly other components such as transmission, brakes, and so on.) As shown, a user may create a graphical or textual program that specifies or implements the functionality of one or both of the controller 92 and the plant 94. For example, a control engineer may use a modeling and simulation tool to create a model (e.g., the graphical program) of the plant 94 and/or to create the algorithm (e.g., the graphical program) for the controller 92.

FIG. 3B illustrates an exemplary system which may perform control and/or simulation functions. As shown, the controller 92 may be implemented by a computer system 82 or other device (e.g., including a processor and memory medium and/or including a programmable hardware element) that executes or implements a graphical program. In a similar manner, the plant 94 may be implemented by a computer system or other device 144 (e.g., including a processor and memory medium and/or including a programmable hardware element) that executes or implements a graphical (or textual) program or model, or may be implemented in or as a real physical system, e.g., a car engine.

In one embodiment of the invention, one or more graphical programs may be created which are used in performing rapid control prototyping. Rapid Control Prototyping (RCP) generally refers to the process by which a user develops a control algorithm and quickly executes that algorithm on a target controller connected to a real system. The user may develop the control algorithm using a graphical (or textual) program, and the graphical (or textual) program may execute on the controller 92, e.g., on a computer system or other device. The computer system 82 may be a platform that supports real time execution, e.g., a device including a processor that executes a real time operating system (RTOS), or a device including a programmable hardware element.

In one embodiment of the invention, one or more graphical (or textual) programs may be created which are used in performing Hardware in the Loop (HIL) simulation. Hardware in the Loop (HIL) refers to the execution of the plant model 94 in real time to test operation of a real controller 92. For example, once the controller 92 has been designed, it may be expensive and complicated to actually test the controller 92 thoroughly in a real plant, e.g., a real car. Thus, the plant model (implemented by a graphical (or textual) program) is executed in real time to make the real controller 92 “believe” or operate as if it is connected to a real plant, e.g., a real engine.

In the embodiments of FIGS. 1B, 2A, 2B, and 3B above, one or more of the various devices may couple to each other over a network, such as the Internet. In one embodiment, the user operates to select a target device from a plurality of possible target devices for programming or configuration using a program. Thus the user may create a graphical (or textual) program on a computer and use (execute) the graphical (or textual) program on that computer or deploy the graphical (or textual) program to a target device (for remote execution on the target device) that is remotely located from the computer and coupled to the computer through a network.

Graphical software programs which perform data acquisition, analysis and/or presentation, e.g., for measurement, instrumentation control, industrial automation, modeling, or simulation, such as in the applications shown in FIGS. 2A and 2B, may be referred to as virtual instruments.

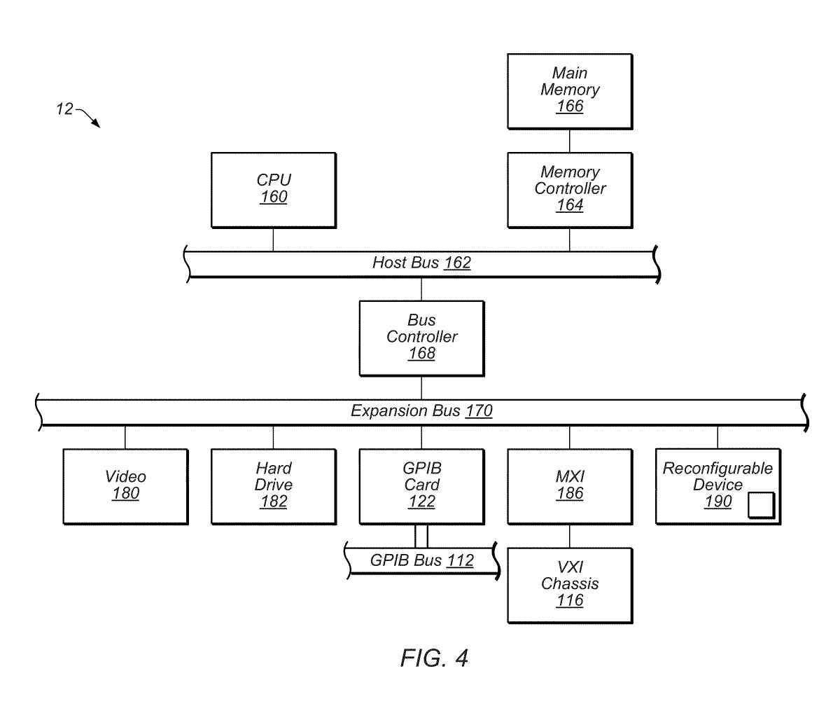

### FIG. 4—Computer System Block Diagram

FIG. 4 is a block diagram representing one embodiment of the computer system 102 and/or 82 illustrated in FIGS. 1A and 1B, or FIGS. 2A and 2B. It is noted that any type of computer system configuration or architecture can be used as desired, and FIG. 4 illustrates a representative PC embodiment. It is also noted that the computer system may be a general purpose computer system, a computer implemented on a card installed in a chassis, or other types of embodiments. Elements of a computer not necessary to understand the present description have been omitted for simplicity.

The computer may include at least one central processing unit or CPU (processor) 160 which is coupled to a processor or host bus 162. The CPU 160 may be any of various types, including an x86 processor, e.g., a Pentium class, a PowerPC processor, a CPU from the SPARC family of RISC processors, as well as others. A memory medium, typically comprising RAM and referred to as main memory, 166 is coupled to the host bus 162 by means of memory controller 164. The main memory 166 may store program instructions implementing embodiments of the present invention. The main memory may also store operating system software, as well as other software for operation of the computer system.

The host bus 162 may be coupled to an expansion or input/output bus 170 by means of a bus controller 168 or bus bridge logic. The expansion bus 170 may be the PCI (Peripheral Component Interconnect) expansion bus, although other bus types can be used. The expansion bus 170 includes slots for various devices such as described above. The computer 82 further comprises a video display subsystem 180 and hard drive 182 coupled to the expansion bus 170. The computer 82 may also comprise a GPIB card 122 coupled to a GPIB bus 112, and/or an MXI device 186 coupled to a VXI chassis 116.

As shown, a device 190 may also be connected to the computer. The device 190 may include a processor and memory which may execute a real time operating system. The device 190 may also or instead comprise a programmable hardware element. The computer system may be configured to deploy a graphical (or textual) program to the device 190 for execution of the program on the device 190. In embodiments using a graphical program, the deployed graphical program may take the form of graphical program instructions or data structures that directly represents the graphical program. Alternatively, the deployed graphical program may take the form of text code (e.g., C code) generated from the graphical program. As another example, the deployed graphical program may take the form of compiled code generated from either the graphical program or from text code that in turn was generated from the graphical program.

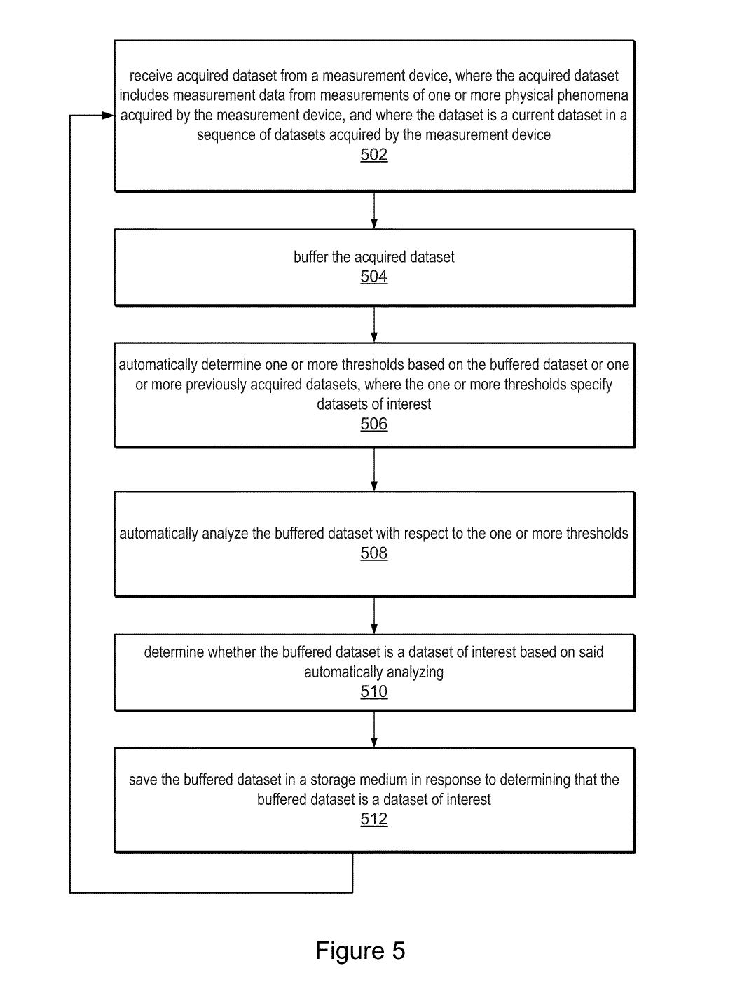

FIG. 5—Flowchart of a Method for Capturing Data Sets of Interest from a Data Acquisition Data Stream

FIG. 5 illustrates a method for capturing data sets of interest from a data acquisition data stream, according to one embodiment. The method shown in FIG. 5 may be used in conjunction with any of the computer systems or devices shown in the above Figures, among other devices. In various embodiments, some of the method elements shown may be performed concurrently, in a different order than shown, or may be omitted. Additional method elements may also be performed as desired. As shown, this method may operate as follows.

In 502, an acquired dataset may be received from a measurement device, where the acquired dataset includes measurement data from measurements of one or more physical phenomena acquired by the measurement device. For example, the dataset may be a current dataset in a sequence (i.e., stream) of datasets acquired by the measurement device. The measurement data may be any type of measurement data desired. For example, in some embodiments, each acquired dataset may include waveform data, although any other form of measurement data may be used as desired. Additionally, the particular phenomena represented by the measurement data may be of any type. Thus, for example, the waveform data may be or include voltage data.

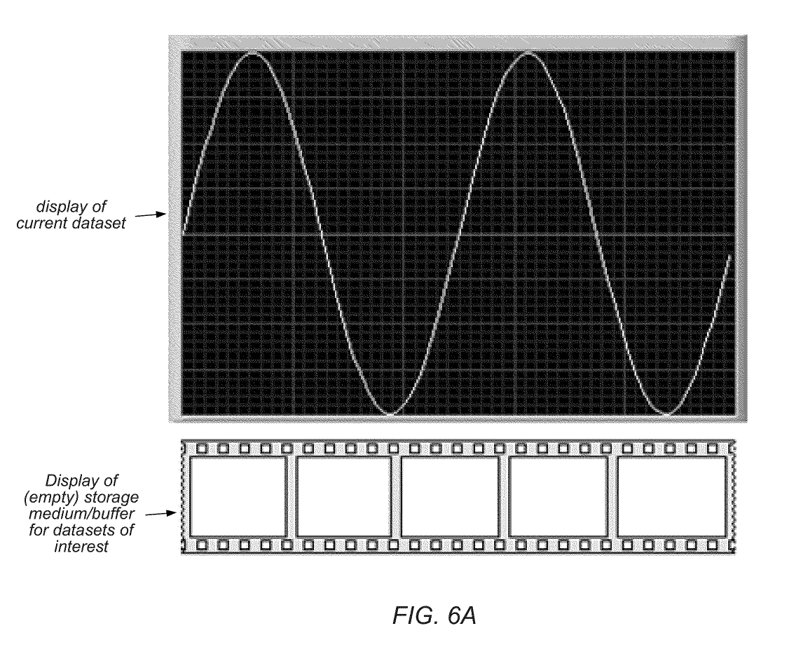

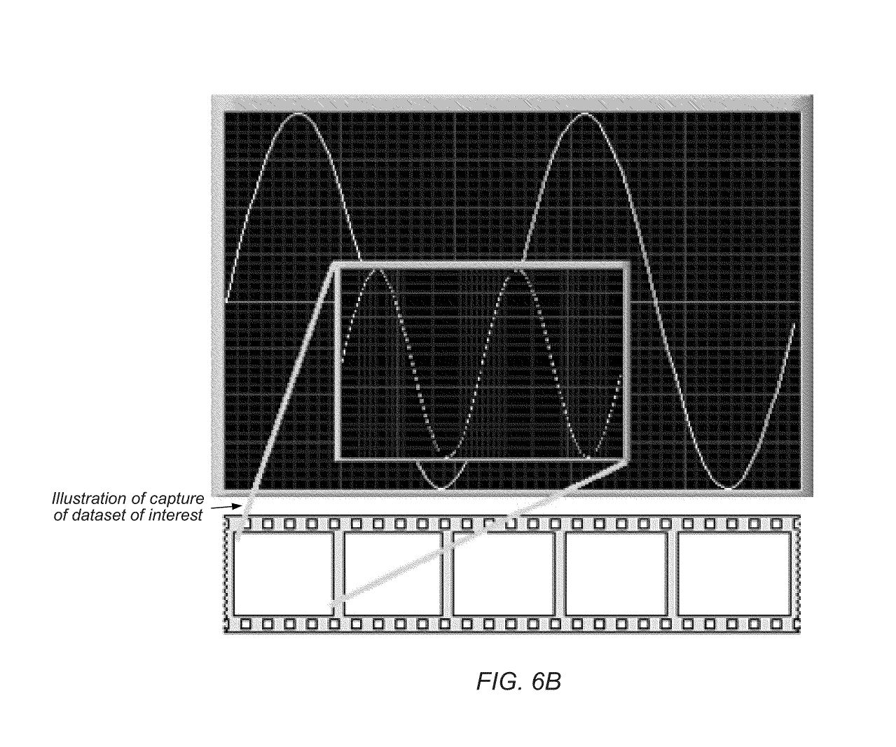

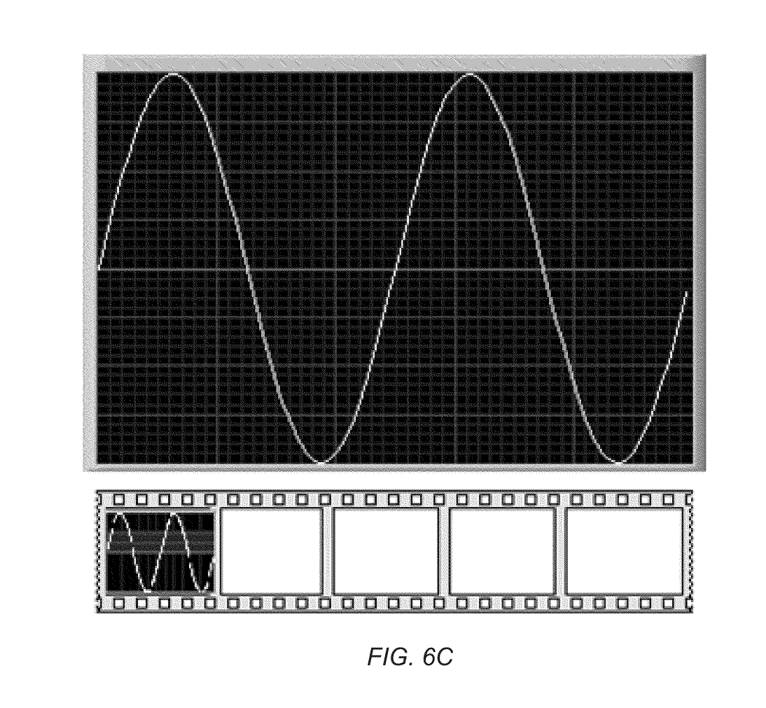

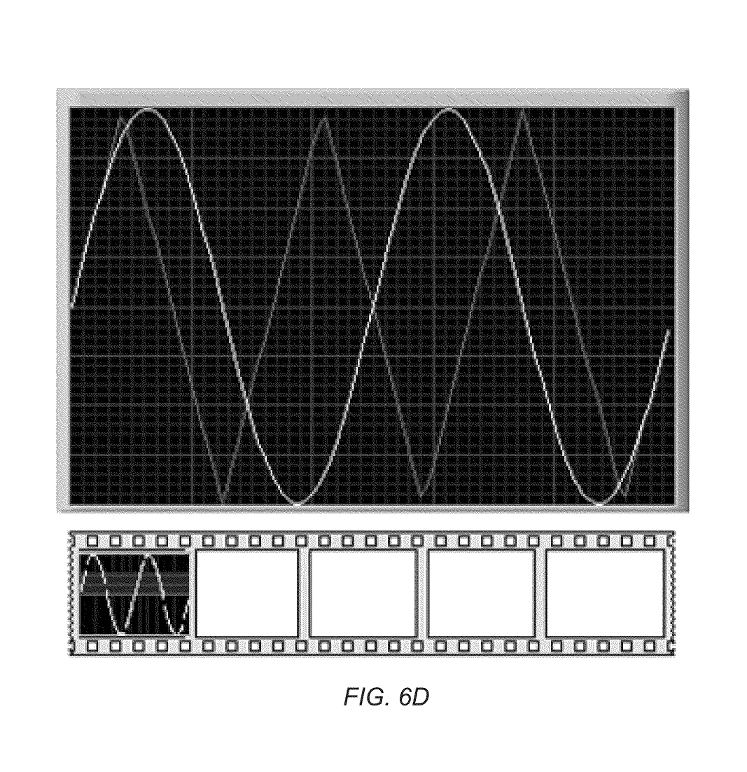

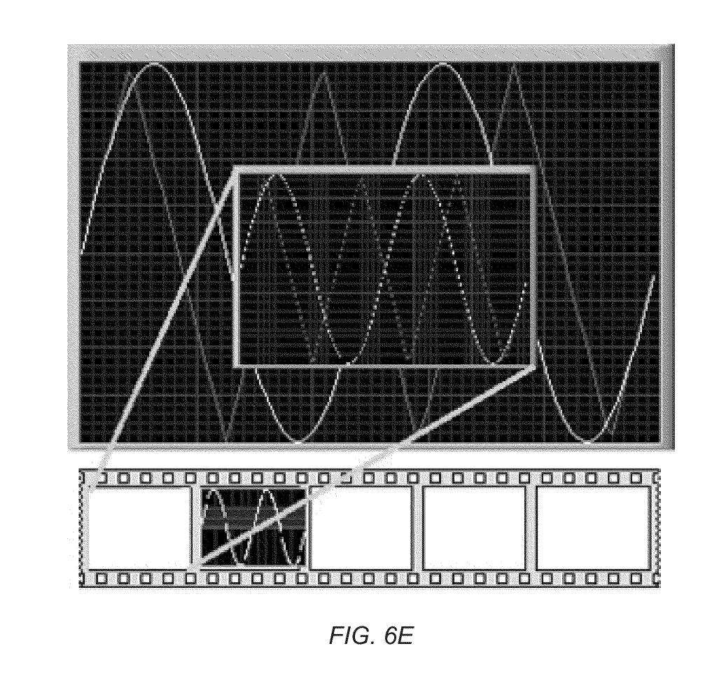

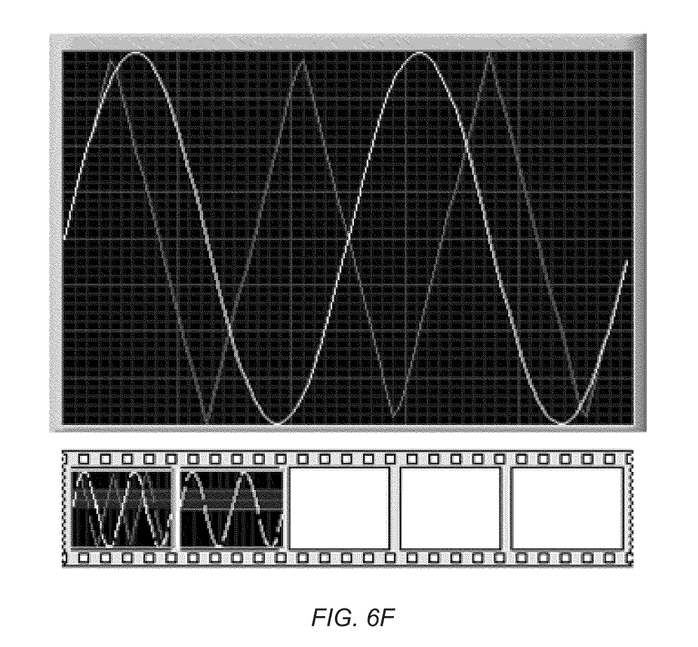

In 504, the acquired dataset may be buffered, resulting in a buffered dataset. In other words, the received acquired dataset may be stored in a buffer, i.e., a memory buffer, from which the dataset may be subsequently read. In some embodiments, the buffered dataset may be displayed, as will be described below with reference to FIGS. 6A-6F.

In 506, one or more thresholds may be automatically determined based on the buffered dataset or one or more previously acquired datasets, where the one or more thresholds specify datasets of interest. Said another way, datasets of interest (e.g., of interest to the user, a process, etc.) may be specified via one or more thresholds (i.e., threshold values) to be applied to the data sets to identify those of interest. These thresholds may be static, e.g., retrieved from a file, or may be dynamic, e.g., determined in response to user input and/or based on the current acquired dataset or one or more previous acquired datasets, as will be described in detail below.

In 508, the buffered dataset may be automatically analyzed with respect to the one or more thresholds. For example, the method may compare data in or of the buffered dataset to the one or more thresholds. Note that any types of analysis may be employed as desired. For example, the method may simply compare the acquired data itself to the one or more thresholds, or may process the data in some way and compare the results to the one or more thresholds, e.g., computing moving averages and comparing them to a threshold value, calculating standard deviation of the dataset and comparing to a respective threshold, etc.

In 510, a determination may be made as to whether the buffered dataset is a dataset of interest based on the automatic analysis of 508, and in 512, the buffered dataset may be stored in a storage medium (i.e., a memory medium) in response to determining that the buffered dataset is a dataset of interest. In various embodiments, the storage medium may itself be a buffer, e.g., in a volatile memory such as RAM, or may be a persistent (non-volatile) storage medium, e.g., flash memory, disk drive, etc. In one embodiment, user feedback may be provided in response to said determining that the buffered dataset is a dataset of interest. For example, an audible, visual, or haptic cue may be provided to the user to indicate determination of the dataset of interest.

As FIG. 5 shows, in some embodiments, the method may further include repeating the above receiving, buffering, automatically determining one or more thresholds, analyzing, and determining whether the buffered dataset is a dataset of interest for each acquired dataset in the sequence of datasets, one or more times in an iterative manner. Moreover, for each buffered dataset that meets the desired criteria, the repeating may further include saving the buffered dataset (of interest), as per 512.

Thus, embodiments of the above method may provide for intelligent easy capture of datasets of interest in a sequence or stream of acquired datasets. The following presents various further exemplary embodiments.

### Further Embodiments

The following describes various exemplary embodiments of the method of FIG. 5, although it should be noted that the particular embodiments described are meant to be exemplary only, and are not intended to limit the invention to any particular form, function, or appearance. FIGS. 6A-6F present exemplary screenshots illustrating various aspects of the present techniques, according to one embodiment.

As noted above, embodiments of the techniques disclosed herein may operate to intelligently and automatically capture potential data of interest. In one embodiment, a dataset that is determined to be of interest may be saved to a short buffer (depicted in FIGS. 6A-6F as a “filmstrip”) that is available to the user (or process) for further analysis or persistent storage.

In one embodiment, the method may include displaying each acquired dataset via a display device in response to the receiving (of 502). FIG. 6A is an exemplary screenshot illustrating an embodiment of a graphical user interface (GUI) in which a current dataset (in this case, waveform data) is displayed in the top window of the GUI (displayed on a display device). In other words, the (current) dataset has been buffered (per 504) and displayed to the user. In this exemplary embodiment, the displayed dataset represents a signal that appears on a channel (of the measurement device). As FIG. 6A also shows, in this embodiment the GUI further illustrates a (currently empty) buffer for captured datasets of interest as a “filmstrip” below the display of the current dataset. It should be noted that the visual “filmstrip” metaphor is but one way to illustrate this buffer, and that any other illustrations or metaphors may be used as desired.

FIG. 6B is an exemplary screenshot illustrating capture (or designation) of a dataset of interest, according to one embodiment. As indicated, in this embodiment, the analysis of 508 has resulted in a determination that the current dataset (i.e., the waveform data displayed in FIGS. 6A and 6B) is “of interest”, and so the capture of the dataset is illustrated, including indicating the storing of the buffered dataset in the storage medium, as per 512. Said another way, FIG. 6C shows a visual indication to the user that the dataset is being or has been captured.

In some embodiments, the captured dataset of interest may be displayed at a lower resolution than that of the displayed corresponding buffered dataset. For example, in one embodiment, the method may take a “screenshot” of the displayed buffered dataset, and reduce the screenshot to a thumbnail image, e.g., displayed in the “filmstrip” (or other GUI element or structure), as illustrated in FIG. 6C. Note that saving the dataset of interest may include saving all of the buffered dataset. Additionally, or alternatively, the dataset of interest may be processed prior to saving, e.g., filtered, smoothed, indexed, etc., as desired.

In one embodiment, the user may interact with the thumbnail image, e.g., to view the image/data in greater detail (higher resolution), to view additional data associated with but not contained in the thumbnail image, to manipulate the image (e.g., with modifications, annotations, additional cursors, additional measurements, and so forth), to save the image or additional data to some designated storage, e.g., a file, to designate or use the data contained in the thumbnail as a reference waveform, e.g., which may be overlaid on new datasets, or to flag it for further viewing, e.g., in an application. For example, the method may include receiving user input selecting a first dataset of interest of the sequence of datasets of interest. In response to this user input, the method may perform one or more of: displaying the first dataset of interest, displaying additional data associated with but not contained in the first dataset of interest, augmenting the first dataset of interest in response to further user input, including adding one or more of: annotations to the first dataset of interest, one or more cursors to the first dataset of interest, or additional measurement values to the first dataset of interest, saving the first dataset of interest to another storage medium, e.g., long term storage, flagging the first dataset for more detailed viewing or analysis, loading the first dataset of interest in an analysis tool for further analysis, or specifying the first dataset of interest as a reference dataset for analyzing subsequent acquired datasets, among others.

Due to the repeating of the method elements of the method of FIG. 5, the method may further include displaying a sequence of datasets of interest resulting from the repeating of the saving of 512. Following the above, the sequence of datasets of interest may be displayed at a lower resolution than the acquired datasets, e.g., as a sequence of thumbnail images of the datasets of interest. Thus, displaying the sequence of datasets of interest may include displaying a sequence of thumbnail images of the datasets of interest.

While FIG. 6A illustrates display of signal data received on one channel, the sequence of datasets may also include datasets of data received on other channels. FIG. 6D illustrates display of a measurement results data image that includes the dataset of FIG. 6A (sinusoidal waveform) as well as a dataset from a new signal (triangular waveform), according to one embodiment. FIG. 6E illustrates a visual indication to a user that a second dataset of interest has been captured, according to one embodiment. Accordingly, FIG. 6F illustrates addition of a stored thumbnail image of the captured second dataset of FIG. 6E, according to one embodiment. Note that the previous (first) captured dataset of interest has been moved one slot to the right.

In one embodiment, images/datasets of interest not saved or flagged (for saving) by the time the filmstrip (or other GUI element/structure) is filled, i.e., upon reaching some maximum number of currently displayed datasets of interest (e.g., thumbnail images), may be automatically deleted, e.g., may “slide off” the filmstrip as newer images are added to the other side of the filmstrip. In other words, the “filmstrip” may operate as a queue, where in case of an overflow the oldest images/datasets of interest are dropped from the display, and possibly deleted from the storage medium in which they are stored.

Note than in various embodiments, there may be numerous factors that determine or characterize datasets of interest, and thus the analyzing may identify any of a wide variety of attributes of the acquired dataset(s). For example, the analyzing may include one or more of the following (among others):
a) identifying presence or absence of a specified signal in the acquired dataset; an unconnected analog probe will often show characteristics such as a mean value near zero and low standard deviation and/or RMS (root mean square). Note that absence of signal on enabled signals (or channels) generally indicates that the data are not of interest.
b) identifying presence of a new signal in the acquired dataset, or identifying a difference of (or change in) a signal in the acquired dataset with respect to one or more previous acquired datasets or a specified reference dataset, where the difference exceeds a specified threshold; when a user moves a probe to a new signal, or a signal changes characteristics substantially, this may indicate new data of interest. Such a change in signal may be identified based on any of a variety of measurement characteristics of the signal, including, but not limited to, mean value, frequency, amplitude, RMS, and standard deviation.
c) identifying stable presence of a new signal in the acquired dataset; while connecting/holding probes to a DUT, a user may sequentially connect them to the correct probe locations, and may encounter transient events while connecting or may briefly connect them to incorrect probe locations. A series of datasets with consistent, similar measurement characteristics (e.g., mean value, frequency, etc.), but unique or distinct from previously identified signals, may indicate that the user has settled on a new probe location of interest, and that the dataset is of interest.
d) identifying an outlier or anomalous dataset with respect to previous and subsequent datasets, e.g., anomalies in repetitive events; many common measurements and trigger configurations yield a trigger configuration that occurs thousands or millions of times per second, and most or all of these datasets generally contain very similar data to the datasets immediately before and after them. When an anomaly or unusual condition occurs, a single dataset will have different characteristics (e.g., mean, frequency, etc.), but the following (next) dataset will resume the prior consistently similar behavior. An anomalous or unusual dataset such as this may be of interest.

Accordingly, the analyzing may include comparing one or more of the following against respective thresholds of the one or more thresholds: mean value of the buffered dataset, standard deviation of the buffered dataset, frequency of a signal in the dataset, or amplitude of a signal in the dataset, among others. Similarly, determining whether the dataset is a dataset of interest may include determining one or more of: presence of a signal in the dataset, difference of the signal in the dataset from a signal in an immediately previous dataset, stability of the signal in the dataset with respect to the signal in one or more immediately previous datasets, or stability of signal presence of the signal in the dataset with respect to the signal in one or more immediately previous datasets, among others.

In one embodiment, a “persistence” feature or criterion may be enabled, e.g., via user input, where many captured datasets are overlaid on a single display. The method (e.g., analysis) may consider “persistence time”, i.e., the duration for which each captured dataset is overlaid on said single display, as part of considering, determining, or identifying, stability of a signal. As an alternative to signal stability, in some embodiments, very slow triggering signals may be identified. For example, if signals generate triggers very slowly (say, significantly less than 1 trigger per second), it may be desirable to capture every trigger case with a different signal rather than applying the stability method. Further factors may also be considered, e.g., number of edges, inflection points, and rise time, among other signal attributes.

In some embodiments, the one or more thresholds may be with respect to differences between the measurements of the dataset and the one or more previously acquired datasets, or differences in measurements between the dataset and previously determined datasets of interest.

Moreover, in some embodiments, dataset captures that are significantly separated in time, or are separated by detected absence of signal, may be demarcated with some additional visual indication, e.g., in the filmstrip, e.g., with added space between successive “frames” or images, use of ellipses between frames, special symbols, etc., as desired.

Thus, various embodiments of the techniques disclosed herein may provide for intelligent capture of datasets of interest in a stream or sequence of acquired datasets.

It should be noted that any of the features and limitations regarding the novel techniques disclosed herein may be used in any combinations as desired.

Although the embodiments above have been described in considerable detail, numerous variations and modifications will become apparent to those skilled in the art once the above disclosure is fully appreciated. It is intended that the following claims be interpreted to embrace all such variations and modifications.

We claim:

1. A non-transitory computer accessible memory medium that stores program instructions executable by a processor to implement:
receiving an acquired dataset from a measurement device, wherein the acquired dataset comprises measurement data from measurements of one or more physical phenomena acquired by the measurement device, and wherein the dataset is a current dataset in a sequence of datasets acquired by the measurement device;
buffering the acquired dataset, resulting in a buffered dataset;
automatically determining one or more thresholds based on the buffered dataset or one or more previously acquired datasets, wherein the one or more thresholds specify datasets of interest;
automatically analyzing the buffered dataset with respect to the one or more thresholds;
determining whether the buffered dataset is a dataset of interest based on said automatically analyzing; and
in response to determining that the buffered dataset is a dataset of interest, saving the buffered dataset in a storage medium.

2. The non-transitory computer accessible memory medium of claim 1, wherein each acquired dataset comprises waveform data.

3. The non-transitory computer accessible memory medium of claim 2, wherein the waveform data comprises voltage data.

4. The non-transitory computer accessible memory medium of claim 1, wherein the program instructions are further executable to implement:
repeating said receiving, said buffering, said automatically determining one or more thresholds, said analyzing, and said determining whether the buffered dataset is a dataset of interest for each acquired dataset in the sequence of datasets, wherein for each buffered dataset that meets the desired criteria, said repeating further comprises said saving the buffered dataset.

5. The non-transitory computer accessible memory medium of claim 4, wherein the program instructions are further executable to implement:
displaying each acquired dataset via a display device in response to said receiving; and
displaying a sequence of datasets of interest resulting from said repeating said saving, wherein the sequence of datasets of interest are displayed at a lower resolution than the acquired datasets.

6. The non-transitory computer accessible memory medium of claim 5, wherein said displaying the sequence of datasets of interest comprises:
displaying a sequence of thumbnail images of the datasets of interest.

7. The non-transitory computer accessible memory medium of claim 5, wherein the program instructions are further executable to implement:
receiving user input selecting a first dataset of interest of the sequence of datasets of interest; and
in response to said receiving user input selecting the first dataset of interest, performing one or more of:
displaying the first dataset of interest;
displaying additional data associated with but not contained in the first dataset of interest;
augmenting the first dataset of interest in response to further user input, comprising one or more of:
adding annotations to the first dataset of interest;
adding one or more cursors to the first dataset of interest; or
adding additional measurement values to the first dataset of interest;
saving the first dataset of interest to a another storage medium;
flagging the first dataset for more detailed viewing or analysis;
loading the first dataset of interest in an analysis tool for further analysis; or
specifying the first dataset of interest as a reference dataset for analyzing subsequent acquired datasets.

8. The non-transitory computer accessible memory medium of claim 1, wherein said analyzing comprises performing one or more of:
identifying presence or absence of a specified signal in the acquired dataset;
identifying presence of a new signal in the acquired dataset;
identifying a difference of a signal in the acquired dataset with respect to one or more previous acquired datasets or a specified reference dataset, wherein the difference exceeds a specified threshold;
identifying stable presence of a new signal in the acquired dataset; or
identifying an outlier or anomalous dataset with respect to previous and subsequent datasets.

9. The non-transitory computer accessible memory medium of claim 1, wherein said analyzing comprises comparing one or more of the following against respective thresholds of the one or more thresholds:
mean value of the buffered dataset;
standard deviation of the buffered dataset;
frequency of a signal in the dataset; or
amplitude of a signal in the dataset.

10. The non-transitory computer accessible memory medium of claim 1, wherein determining whether the dataset is a dataset of interest comprises determining one or more of:
presence of a signal in the dataset;
difference of the signal in the dataset from a signal in an immediately previous dataset;
stability of the signal in the dataset with respect to the signal in one or more immediately previous datasets; or
stability of signal presence of the signal in the dataset with respect to the signal in one or more immediately previous datasets.

11. The non-transitory computer accessible memory medium of claim 1, wherein the program instructions are further executable to implement:
providing user feedback in response to said determining that the buffered dataset is a dataset of interest, wherein the user feedback comprises an audible, visual, or haptic cue.

12. The non-transitory computer accessible memory medium of claim 1, wherein the one or more thresholds are with respect to one or more of:
differences between the measurements of the dataset and the one or more previously acquired datasets; or
differences in measurements between the dataset and previously determined datasets of interest.

13. A method, comprising:
utilizing a computer to perform:
receiving an acquired dataset from a measurement device, wherein the acquired dataset comprises measurement data from measurements of one or more physical phenomena acquired by the measurement device, and wherein the dataset is a current dataset in a sequence of datasets acquired by the measurement device;
buffering the acquired dataset, resulting in a buffered dataset;
automatically determining one or more thresholds based on the buffered dataset or one or more previously acquired datasets, wherein the one or more thresholds specify datasets of interest;
automatically analyzing the buffered dataset with respect to the one or more thresholds;
determining whether the buffered dataset is a dataset of interest based on said automatically analyzing; and
in response to determining that the buffered dataset is a dataset of interest, saving the buffered dataset in a storage medium.

14. The method of claim 13, wherein the waveform data comprises voltage data.

15. The method of claim 13, further comprising:
utilizing the computer to perform:
repeating said receiving, said buffering, said automatically determining one or more thresholds, said analyzing, and said determining whether the buffered dataset is a dataset of interest for each acquired dataset in the sequence of datasets, wherein for each buffered dataset that meets the desired criteria, said repeating further comprises said saving the buffered dataset.

16. The method of claim 15, further comprising:
utilizing the computer to perform:
displaying each acquired dataset via a display device in response to said receiving; and
displaying a sequence of datasets of interest resulting from said repeating said saving, wherein the sequence of datasets of interest are displayed at a lower resolution than the acquired datasets.

17. The method of claim 16, further comprising:
utilizing the computer to perform:
receiving user input selecting a first dataset of interest of the sequence of datasets of interest; and
in response to said receiving user input selecting the first dataset of interest, performing one or more of:
displaying the first dataset of interest;
displaying additional data associated with but not contained in the first dataset of interest;
augmenting the first dataset of interest in response to further user input, comprising one or more of:
adding annotations to the first dataset of interest;
adding one or more cursors to the first dataset of interest; or
adding additional measurement values to the first dataset of interest;
saving the first dataset of interest to another storage medium;
flagging the first dataset for more detailed viewing or analysis;
loading the first dataset of interest in an analysis tool for further analysis; or
specifying the first dataset of interest as a reference dataset for analyzing subsequent acquired datasets.

18. The method of claim 13, wherein said analyzing comprises performing one or more of:
identifying presence or absence of a specified signal in the acquired dataset;
identifying presence of a new signal in the acquired dataset;
identifying a difference of a signal in the acquired dataset with respect to one or more previous acquired datasets or a specified reference dataset, wherein the difference exceeds a specified threshold;
identifying stable presence of a new signal in the acquired dataset; or
identifying an outlier or anomalous dataset with respect to previous and subsequent datasets.

19. The method of claim 13, further comprising:
utilizing the computer to perform:
providing user feedback in response to said determining that the buffered dataset is a dataset of interest, wherein the user feedback comprises an audible, visual, or haptic cue.

20. A system, comprising:
a memory medium;
a processing element, coupled to the memory medium, wherein the processing element is configured to:
receive an acquired dataset from a measurement device, wherein the acquired dataset comprises measurement data from measurements of one or more physical phenomena acquired by the measurement device, and wherein the dataset is a current dataset in a sequence of datasets acquired by the measurement device;
buffer the acquired dataset, resulting in a buffered dataset;
automatically determine one or more thresholds based on the buffered dataset or one or more previously acquired datasets, wherein the one or more thresholds specify datasets of interest;
automatically analyze the buffered dataset with respect to the one or more thresholds;
determine whether the buffered dataset is a dataset of interest based on said automatically analyzing; and
in response to determining that the buffered dataset is a dataset of interest, save the buffered dataset in a storage medium.
